(19) United States
(12) Patent Application Publication
(10) Pub. No.: US 2007/0096244 A1
(43) Pub. Date: May 3, 2007

(54) Variable field device for process automation technology

(75) Inventor: Joerg Roth, Lorrach (DE)

Correspondence Address: BACON & THOMAS, PLLC, 625 SLATERS LANE, FOURTH FLOOR, ALEXANDRIA, VA, 22314, US

(73) Assignee: Endress + Hauser Flowetec AG, Reinach (CH)

(21) Appl. No.: 10/559,459

(22) PCT Filed: Jun. 2, 2004
(86) PCT No.: PCT/EP04/05963

§ 371 Date: Oct. 30, 2006

(30) Foreign Application Priority Data
Jun. 3, 2003 (DE) 103 25 277.0

(51) Int. Cl. H01L 27/095

(52) U.S. Cl. 257/478

(57) ABSTRACT

In a variable field device for process automation technology, wherein the field device is connected to an external communication medium for data transmission and wherein functionalities of the field device are application-specifically adaptable, the field device provides only few, basic functions (e.g. measured value production) and application-specific functionalities (e.g. frequency/pulse outputs) are implemented by separate function units, which are connected to the communication medium.

The invention relates to a variable field device for process automation technology as defined in the preamble of claim 1.

In process automation technology, field devices are often used, which serve for the registering and/or influencing of process variables. Examples of such field devices are fill level measuring devices, mass flow rate measuring devices, pressure and temperature measuring devices, pH-redox measuring devices, conductivity measuring devices, etc, which, as measuring devices, register the corresponding process variables fill level, flow rate, pressure, temperature, pH-value and conductivity. A large number of such field devices are manufactured and sold by the firm Endress + Hauser®. Frequently, field devices are connected via a field bus with superordinated units, e.g. process control systems and/or control units. These superordinated units serve for process visualization, process monitoring, process control and for operating the field devices attached to the field bus.

Examples of such fieldbus systems are CAN®, CAN-OPEN, HART®, Profibus® PA, Profibus® DP, Profibus® FMS, Foundation® Fieldbus, etc.

With the help of these field bus systems, it is not only possible to transmit measured values from a sensor to a central control unit, but also to operate field devices remotely from the process control system. To this end, special hardware and software components are necessary, both in the field device and in the control system.

Today's field devices are equipped with always more functionalities, which are derived directly or indirectly from the real purpose of the field device—to measure a process variable. The manufacturers of field devices try to move as many functions as possible into the devices, in order, in this way, to fulfill “all”, i.e. also special, wishes of customers. A main part of these functionalities is implemented by microprocessors in the field device. In the past, almost the entire computing power of these microprocessors was needed for the actual measuring task. With today's microprocessors, there is sufficient computing power available in the field devices for implementing a multitude of functionalities. This is evident from a comparison of two Coriolis mass flow rate measuring devices of the firm Endress + Hauser®. While the m-Point® in the year 1989 had 37 control panels, a Promass® 83 today has already 329 control panels, which must be mastered by the user. This growth in functionality means, on the one hand, for the device manufacturer, an increased manufacturing and developmental expense, and, for the user, an increased complexity of handling. Both are associated with significant costs. In this connection, the complex handbooks and the schooling of the personnel charged with device operation can be mentioned. The single user does not need, as a rule, all available functionalities, but, instead, only a certain subset thereof.

Also, it is no longer clearly apparent for the user, how a measured value can be processed further in a field device complicated in this manner, or what effects certain parameter changes have on this further processing. If, in the case of a changing of units, e.g. from liters to gallons, the original measured value is immediately converted, or only converted for the display. What effects such a change in units has on quantities derived from the original measured value, is not at all transparent for the user.

An object of the invention is, therefore, to provide for process automation technology a variable field device, which has only the functions required by the user, i.e. which is application-specifically adaptable, easily manufacturable at favorable cost, easy to handle, and transparent for the user as regards further processing of the measured values.

This object is achieved by the variable field device defined in claim 1, respectively by the method defined in claim 14.

Advantageous further developments of the invention are defined in the dependent claims.

An essential idea of the invention is that functions of a field device be distributed. The actual field device provides only some few, basic functions (e.g. measured value production). Application specific functionalities (e.g. frequency/pulse outputs) are implemented by separate, function units, which are spatially separated from the field device. Field devices and function units are connected to an appropriate communication medium for data exchange. In this way, the field device is very variable and application-specifically adaptable. It has no unnecessary functionalities. Also the operation of such a field device is extremely simple, since it has only the functions needed by the user. Furthermore, the transparency of the further processing of the measured values is evident for the user. The field device delivers a measured value, which is processed further in appropriate function units. As a result of the simple structure, the variable field device is very favorable as regards cost both in manufacture and in handling.

In a further development of the invention, the communication medium is a two-wire supply cable, via which the field devices and the function units are supplied with current and voltage.

In a further development of the invention, the communication medium permits multiple access with a plurality of data channels. In this way, the measured values of different field devices can be transmitted simultaneously, or essentially simultaneously.

The multiple access can occur according to one of the known transmission methods, e.g. FDMA (frequency division multiple access), TDMA (time division multiple access) or CDMA (code division multiple access).

The transmission of data on the communication medium occurs without information concerning the data transmitter, or data receiver, as the case may be. In this way, the data transmission is correspondingly simple and fast, and no complex communication protocol is used.

The data transmission rate on the communication medium should amount to more than 31.25 kbit/sec, in order to be able to process measured values further as quickly as possible.

The communication medium can be e.g. a twisted two-wire cable.

In a further development of the invention, the data transmission rate for each data channel is application-specifically adaptable. In this way, field devices, which register rapidly changing process variables, can transmit their data at relatively high speed via the communication medium.

According to a further development of the invention, the channel capacity of a data channel is continuously monitored and the data transmission rate of this channel is appropriately adapted. In this way, the influence of disturbance signals (e.g. switching pulses) is lessened.

In a special embodiment, the field device is a Coriolis mass flow rate meter, in which more than 100 measurements are executed per second, and the corresponding measured values are transmitted over one of the data channels.

In a further development of the invention, three measured values, namely mass flow rate, density and temperature are measured for the medium flowing through the Coriolis mass flow meter.

Additionally, the measured values are transmitted with a time stamp, in order to enable exact association of the measurement and the point in time at which the measurement was taken.

The measured values are, in advantageous manner, transmitted as 32-bit, floating point values (IEEE format).

The invention will now be explained in further detail on the basis of an example of an embodiment and accompanying drawing, the sole FIGURE of which shows as follows:

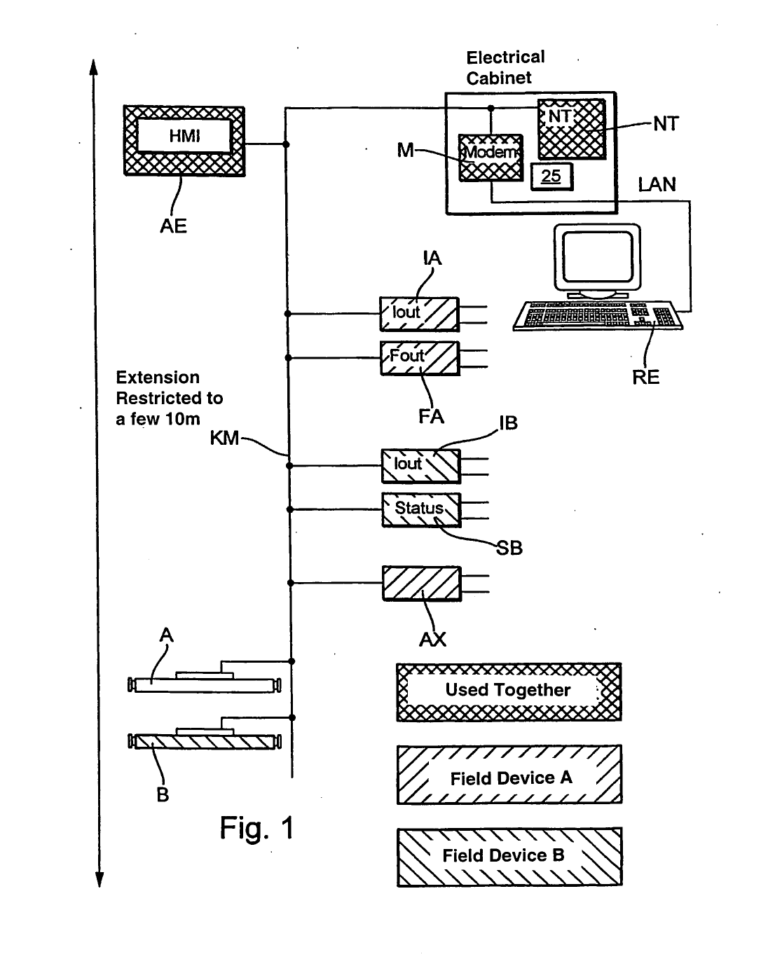

FIG. 1 schematically, two, variable, field devices, which are connected with different function units via a communication medium.

FIG. 1 shows two field devices A, B schematically. Each of these field devices A, B is a Coriolis mass flow meter. The two field devices A, B are connected via a communication medium KM with a plurality of function units IA, FA, IB, SB and X. Furthermore, the communication medium KM, which can be a conventional two-wire cable, is connected to a display unit AE. The voltage supply of the field devices A, B, the function units IA, FA, IB, SB and X, and the display unit AE occurs via a power supply NT. A modem M connects the communication medium KM with a further network LAN (local area network), to which, by way of example, a computing unit RE is connected. In this way, e.g. measured values of the field devices can be transmitted to the computer unit RE for process monitoring or process visualization. The display unit AE serves for displaying measured values or status information of the two field devices A, B.

Function unit IA involves a current output. Function unit FA involves a frequency output. Such current and frequency outputs are known from conventional field devices, especially Coriolis mass flow meters. Function unit Ax is any, not-further-defined, function unit, with an associated output. Function unit IB likewise involves a current output, while function unit SB has a status output.

The functioning of the invention will now be explained in greater detail.

The functionality of the field devices A and B is distributed in the function units, respectively, IA, FA, and IB, SB, which are spatially separated from the field devices. The two field devices provide only basic functions, such as e.g. production of measured values. In the case of a Coriolis mass flow meter, these are mass flow rate, density and temperature of the medium flowing through the flow meter. All application-specific functionalities are implemented in the additional, separate, function units IA, FA, IB, SB and X.

Each field device A, B transmits its data (measured values) via the communication medium KM to the appropriate function unit IA, FA, X, respectively IB, SB, where the data are processed further.

If a user needs three frequency outputs in the case of a field device, then the user needs only the corresponding function units. Since the field devices have no unnecessary functionalities, they can be very cost competitive, and their operation is easy for the user.

The following estimate gives the net bandwidth requirement of a field device connected to the communication medium KM, when, per measurement, 4 measured values (e.g. mass flow rate, density, temperature, and one more measured value) are determined, and these are provided with a time stamp and transmitted as floating point values in the 32-bit, IEEE format: 200/sec×(4×32 bit+32 bit)=32,000 bit/sec. In order also to be able to exchange configuration data, the net bandwidth is increased to 50,000 bit/sec. Considering also an overhead and a factor of safety, then the bandwidth requirement of a field device lies e.g. at about 100 kbit/sec.

Depending on what the transmission bandwidth of the communication medium allows, correspondingly many field devices can be connected. The transmission bandwidth depends on, among other things, the number of connected components, the length of the line (communication medium) and the type of line (shielded, or not shielded). In the case of a bandwidth of 2 Mbit, about 20 participants (field devices) can be connected to the communication medium KM and simultaneously transmit data, without experiencing mutual interference. Such data transmission rates are provided by conventional components of communication technology (telephone, computer networks), which are mass produced. By the use of such components, the variable field devices, and the necessary function units, of the invention are likewise manufacturable at favorable cost.

Known data transmission methods are e.g. FDMA (Frequency Division Multiple Access), TDMA (Time Division Multiple Access) or CDMA (Code Division Multiple Access), which all permit multiple access.

Since the data of the field devices A, B are sent on different channels, no information concerning the data transmitter, or transmitters, is necessary (in the case of conventional field busses, the data must be complexly packaged in corresponding protocols). Fieldbus systems permit, in part, data transmission rates of only 32.25 kbit/sec. In the case of the present invention, however, significantly higher data transmission rates are possible.

The function units are correspondingly tuned to the channels. The tuning occurs during configuration of the entire system using a configuration unit, which is not described in more detail here. As already mentioned, the configuring of the system is significantly simpler for the user, since the user uses only required function units and the data flow is intuitively transparent. If the unit of a measured value is changed in a field device, then all connected units, such as e.g. the function units, get the changed information.

If e.g. temperature sensors are connected to the communication medium KM, which register the temperature in a large tank, where it is certain that temperature changes only slowly, then it is not reasonable to transmit the temperature values with a data transmission rate of 200/sec. In such case, a significantly lower data transmission rate is sufficient on the corresponding data channel.

Additionally, it is possible to monitor the channel capacity of a data channel continuously and so to adapt the data transmission rate correspondingly. In this way, the influence of disturbing signals, such as can occur during on-switching of motors, can be lessened.

The present invention enables realization of a variable field device simply and cost-effectively.

1-14. (canceled)

15. A variable field device for process automation technology, the variable field device being connected to an external communication medium for data transmission, including:
separate function units connected to the communication medium, wherein:
the functionalities of the field device are application-specifically adaptable; and
the field device provides only basic functions, such as measured value production, and application-specific functionalities, such as frequency/pulse outputs, which are implemented by said separate function units.

16. The variable field device as claimed in claim 15, wherein:
the communication medium is a two-wire supply cable.

17. The variable field device as claimed in claim 15, wherein:
a plurality of data channels offering multiple access are provided on the communication medium.

18. The variable field device as claimed in claim 17, wherein:
said multiple access occurs according to one of the transmission methods FDMA, TDMA or CDMA.

19. The variable field device as claimed in claim 15, wherein:
data on the communication medium are transmitted without information concerning data transmitter and data receiver.

20. The variable field device as claimed in claim 15, wherein:
the data transmission rate on the communication medium is greater than 31.25 kbit/sec.

21. The variable field device as claimed in claim 15, wherein:
the communication medium is a twisted, two-wire cable.

22. The variable field device as claimed in claim 17, wherein:
the data transmission rate on each data channel is application-specifically adaptable.

23. The variable field device as claimed in claim 17, wherein:
the channel capacity of a data channel is continuously monitored and the data transmission rate of this channel is correspondingly adapted.

24. The variable field device as claimed in claim 17, wherein;
the field device is a Coriolis mass flow meter, in which more than 100 measurements are performed per second, and the corresponding measured values are transmitted over one of the data channels.

25. The variable field device as claimed in claim 24, wherein:
at least 3 measured values, mass flow rate, density and temperature, of the medium flowing in said Coriolis mass flow meter are measured per measurement.

26. The variable field device as claimed in claim 25, wherein:
a time stamp is transmitted in addition to the measured values.

27. The variable field device as claimed in claim 25, wherein:
the measured values are transmitted as 32-bit, floating point values (IEEE-format).

28. A method for data transmission for field devices of process automation technology connected to a communication medium, comprising the step of:
sending the data of the field devices independently of one another to separate function units, which are assigned to the field devices.
